(19) United States
(12) Patent Application Publication
(10) Pub. No.: US 2012/0273024 A1
(43) Pub. Date: Nov. 1, 2012

(54) SOLAR CELL MODULE AND METHOD FOR FORMING THE SAME

(75) Inventors: Chu-Jung Ko, Taipei City (TW); Kang-Cheng LIN, Taipei City (TW)

(73) Assignee: MOTECH INDUSTRIES INC.,, New Taipei City (TW)

(21) Appl. No.: 13/240,860

(22) Filed: Sep. 22, 2011

(30) Foreign Application Priority Data
Apr. 27, 2011 (TW) 100114654

(51) Int. Cl. H01L 31/052; H01L 31/0232

(52) U.S. Cl. 136/246; 438/65; 438/66; 257/E31.127

(57) ABSTRACT

A solar cell module includes lower and upper substrates that are spaced apart from each other, a plurality of spaced apart solar cells, a plurality of gratings, and a light-transmissive encapsulant disposed between the lower and upper substrates to encapsulate the solar cells and the gratings. Each of the gratings has a grating center, and four reflecting regions formed around the grating center. Each of the reflecting regions has a light entrance face that has a plurality of valleys and peaks. The valleys and peaks alternate with each other along a direction from the grating center to a corresponding one of the corners of a corresponding one of the four adjacent solar cells.

### CROSS-REFERENCE TO RELATED APPLICATION

This application claims priority of Taiwanese application no. 100114654, filed on Apr. 27, 2011.

### BACKGROUND OF THE INVENTION

1. Field of the Invention

The present invention relates to a solar cell module and a method for forming the same, and more particularly to a solar cell module having gratings disposed between solar cells and a method for forming the same.

2. Description of the Related Art

Referring to FIGS. 1 and 2, a solar cell module 1 disclosed in U.S. Pat. No. 4,235,643 comprises a substrate 11, a plurality of solar cells 12 arranged in a matrix on the substrate 11, and an encapsulant layer 13 coupled to the solar cells 12. In the early process for producing monocrystalline silicon solar cells 12, the silicon wafers cut from a crystal column are circular in shape. If the silicon wafers are not processed to form other shapes, the solar cells 12 made from the silicon wafers are also circular in shape. To prevent short-circuiting of the solar cells 12 due to contact with an adjacent solar cell 12, the solar cells 12 are spaced apart from each other, such that the substrate 11 is formed with a plurality of non-active regions 121. Thus, the effective area of the solar cell module 1 is reduced, and the light entering the non-active regions 121 cannot be utilized, thereby lowering the efficiency of the solar cell module 1.

To overcome these problems, the non-active regions 121 are provided with facets 111 with light reflective properties. Therefore, the light incident onto the non-active regions 121 will be reflected by the facets 111 and directed to the adjacent solar cells 12 for utilization.

However, since the facets 111 are formed by roughening the substrate 11, a relatively thick substrate 11 is required in order to conveniently carry out a surface roughening process, thereby resulting in a high production cost. In addition, upon making the solar cell module 1, the substrate 11 has to be locally roughened to form the facets 111 such that positions where the solar cells 12 are to be placed are defined. If the position or size of each of the facets 111 is not correctly formed, it is possible that the solar cells 12 cannot be exactly placed. Therefore, the facets 111 must be precisely designed, and thus, the manufacture thereof is relatively difficult and inconvenient.

Referring to FIGS. 3 and 4, a polycrystalline silicon solar cell module 2 that is disclosed in U.S. Pat. No. 5,994,641 is shown. Since the polycrystalline silicon is cut from a square silicon ingot, the solar cells 21 made therefrom are generally square in shape. Similarly, non-active regions 211 are formed among adjacent ones of the solar cells 21. A structure body 22 is disposed in each of the non-active regions 211. The structure body 22 includes a metal film 221 formed with a plurality of contiguous V-shaped grooves 222 for reflecting the light incident onto the non-active regions 211 to the surrounding solar cells 21.

However, the extension direction of the contiguous V-shaped grooves 222 will affect the light reflection direction. Therefore, the extension direction of the contiguous V-shaped grooves 222 must match the positions of the solar cells 21. For example, with respect to the crossed area 210 among any four of the solar cells 21 in FIG. 3, the V-shaped grooves 222 are arranged in a horizontal direction and extend in a vertical direction. Such a structure is designed for reflecting the incident light in the horizontal direction. In FIG. 3, the reflection directions of the incident light are indicated by arrows. However, since there are no solar cells 21 in the reflection directions, the design of the structure body 22 at the crossed area 210 is not satisfactory.

On the other hand, for a monocrystalline silicon solar cell module, to enhance the light absorbing area and efficiency of the module, the shape and the arrangement of the monocrystalline silicon solar cell are modified and are different from the configuration shown in FIG. 1. Referring to FIG. 5, the current method for manufacturing the modified monocrystalline silicon solar cell includes subjecting a circular silicon wafer to a four-side cutting operation to form a generally square wafer with four rounded corners 310. The removed four parts are shown by the phantom lines 30 in FIG. 5. Therefore, after the solar cells 31 made from the generally square wafers are connected in series, a generally diamond shaped non-active region 311 is formed among four adjacent ones of the solar cells 31. However, at present, there is no light compensating design for the solar cell module with such configuration.

Since the module configuration, cell shape and cell arrangement of the solar cell module of the abovementioned two US patents are greatly different from those of the existing monocrystalline silicon solar cell module shown in FIG. 5, the light compensating designs for the abovementioned two US patents are not suitable for the existing monocrystalline silicon solar module shown in FIG. 5. Accordingly, it is desired to provide a novel light compensating structure for the monocrystalline silicon solar cell module shown in FIG. 5.

### SUMMARY OF THE INVENTION

Therefore, the object of the present invention is to provide a solar cell module that is relatively easy to manufacture, and that can increase light utilization rate and photoelectric conversion efficiency, and a method for forming the same.

According to one aspect of the present invention, a solar cell module comprises: lower and upper substrates that are spaced apart from each other, the upper substrate being light transmissive; a plurality of spaced apart solar cells disposed between the lower and upper substrates and arranged in a matrix, each of the solar cells having at least four corners; a plurality of gratings disposed between the lower and upper substrates, each of the gratings being formed among four adjacent ones of the solar cells proximate to one of the corners of each of the four adjacent ones of the solar cells, each of the gratings having a grating center and four reflecting regions formed around the grating center, each of the reflecting regions having a light entrance face that faces toward the upper substrate and that has a plurality of valleys and peaks, the valleys and peaks alternating with each other along a direction from the grating center to a corresponding one of the corners of a corresponding one of the four adjacent ones of the solar cells; and a light-transmissive encapsulant disposed between the lower and upper substrates to encapsulate the solar cells and the gratings.

According to another aspect of the present invention, a method for forming a solar cell module comprises: (a) covering a first seal film over a lower substrate; (b) disposing a plurality of solar cells, each of which has at least four corners, on the first seal film so that the solar cells are spaced apart from each other and arranged in a matrix array; (c) disposing a plurality of gratings above the first seal film, each of the gratings being formed among four adjacent ones of the solar cells proximate to one of the corners of each of the four adjacent ones of the solar cells, each of the gratings having a grating center and four reflecting regions formed around the grating center, each of the reflecting regions having a light entrance face that faces away from the lower substrate and that has a plurality of valleys and peaks, the valleys and peaks alternating with each other along a direction from the grating center to a corresponding one of the corners of a corresponding one of the four adjacent ones of the solar cells; (d) covering a second seal film over the solar cells and the gratings; (e) covering an upper substrate over the second seal film; and (f) melting the first and second seal films so that the solar cells and the gratings are encapsulated between the lower and upper substrates.

Preferably, the method further comprises a step of covering a third seal film over the solar cells before step (c). In step (c), the gratings are disposed on the third seal film that is disposed above the lower substrate. In step (f), the first, second, and third seal films are melted together.

### BRIEF DESCRIPTION OF THE DRAWINGS

Other features and advantages of the present invention will become apparent in the following detailed description of the preferred embodiments with reference to the accompanying drawings, of which:

FIG. 1 is a fragmentary schematic top view of a conventional solar cell module;

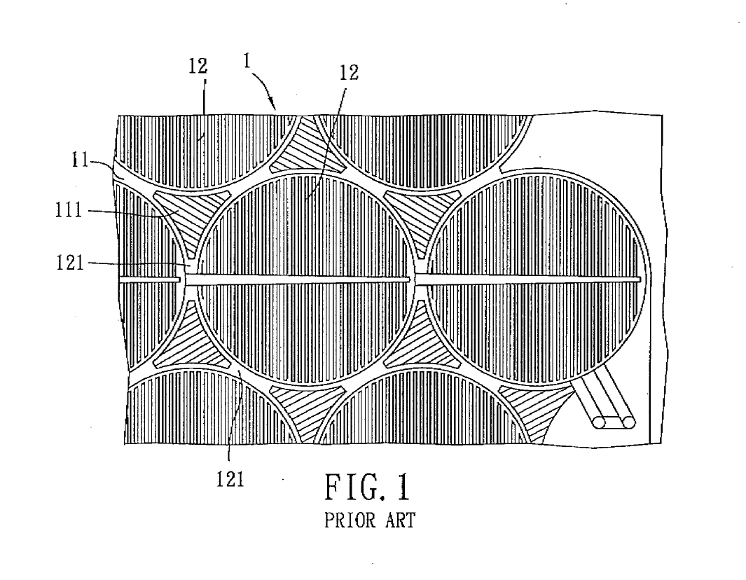

FIG. 2 is a fragmentary partly cross sectional view of the conventional solar cell module of FIG. 1;

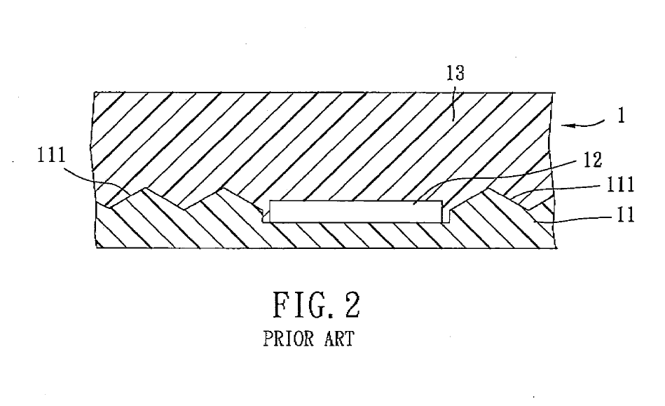

FIG. 3 is a schematic top view of another conventional solar cell module;

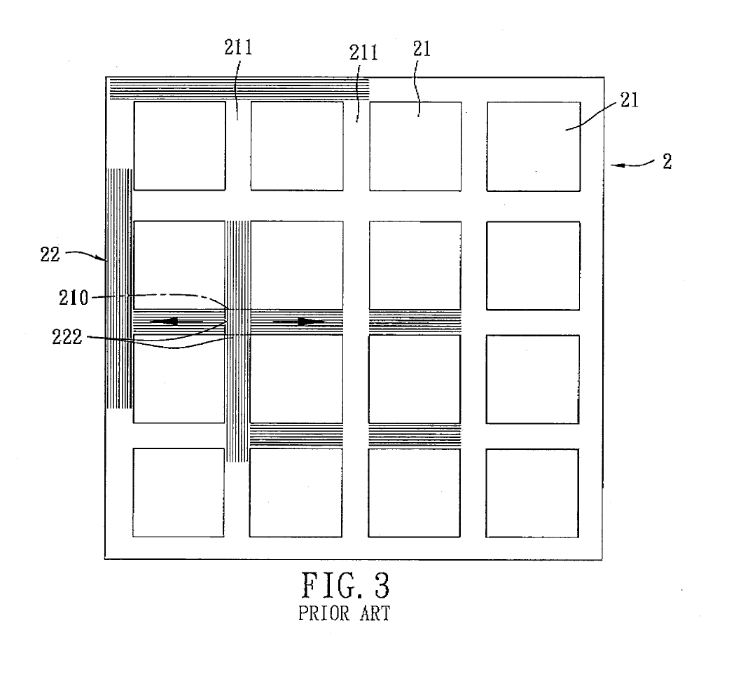

FIG. 4 is a fragmentary schematic side view of a structure body of the conventional solar cell module of FIG. 3;

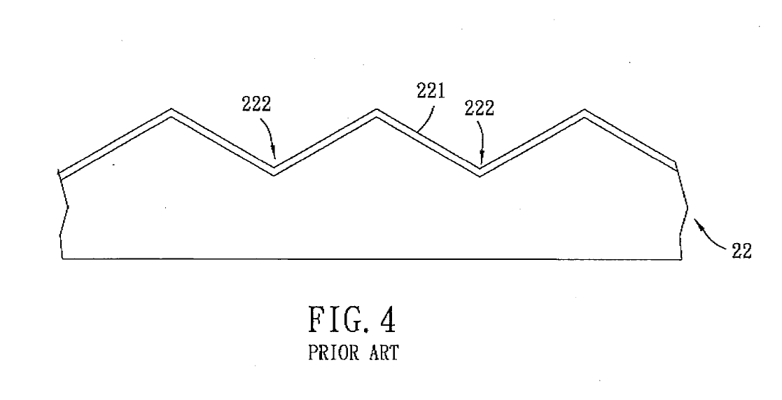

FIG. 5 is a fragmentary schematic view of yet another conventional monocrystalline silicon solar cell module;

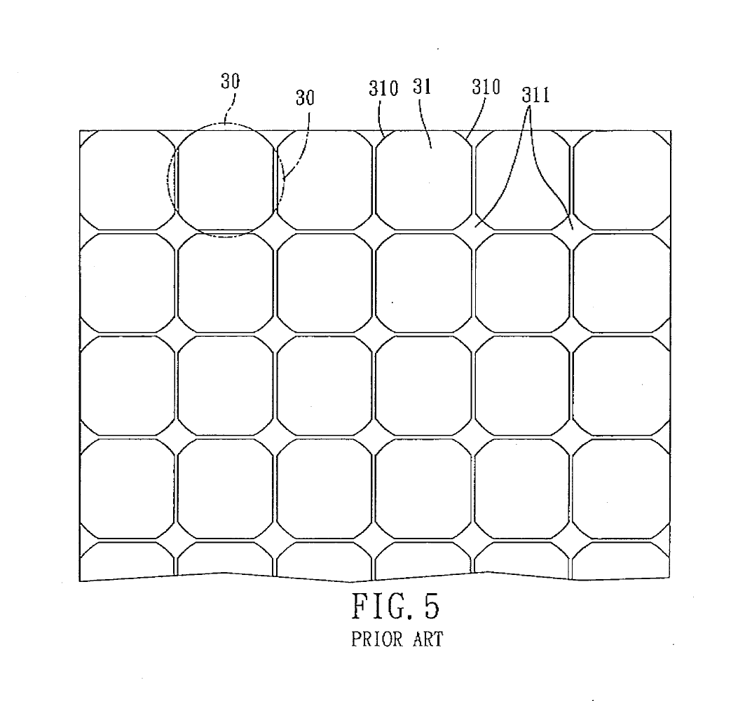

FIG. 6 is fragmentary partly cross sectional view of a first preferred embodiment of a solar cell module according to the present invention;

FIG. 7 is a schematic top view of the first preferred embodiment in which some elements are removed for the sake of clarity;

FIG. 8 is a schematic top view of four solar cells and a grating of the first preferred embodiment;

FIG. 9 is a schematic side view of the grating of the first preferred embodiment;

FIG. 10 is a flow chart of a method for forming a solar cell module of the first embodiment according to the present invention;

FIG. 11 illustrates consecutive steps of the method of FIG. 10;

FIG. 12 is a schematic exploded view illustrating a step of covering a third seal film over the solar cells that is further included in the method of FIG. 11; and

FIG. 13 is a schematic top view of a second preferred embodiment of a solar cell module according to the present invention, in which only four solar cells and a grating are shown.

### DETAILED DESCRIPTION OF THE PREFERRED EMBODIMENTS

Before the present invention is described in greater detail, it should be noted that like components are assigned the same reference numerals throughout the following disclosure.

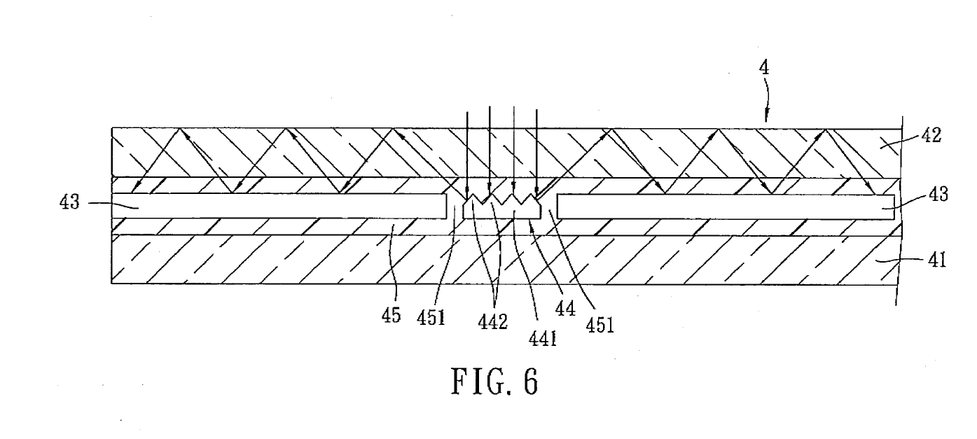

Referring to FIGS. 6, 7 and 8, a first preferred embodiment of a solar cell module 4 of the present invention comprises lower and upper substrates 41, 42 that are spaced apart from each other, a plurality of spaced apart solar cells 43 disposed between the lower and upper substrates 41, 42, a plurality of gratings 44 disposed between the lower and upper substrates 41, 42, and a light-transmissive encapsulant 45.

The lower substrate 41 is also known as a back sheet. The upper substrate 42 is located on a side where sunlight enters, and is made of a light transmissive material, such as a glass.

The solar cells 43 are monocrystalline solar cells arranged in a matrix. Each of the solar cells 43 has four sides 431 and four corners 432 interconnecting the four sides 431. Each of the sides 431 is straight, and each of the corners 432 is beveled to form a beveled side. The corners 432 of four adjacent ones of the solar cells 43 define cooperatively a light compensating area 433. The light compensating area 433 is generally diamond shaped.

Each of the gratings 44 is formed in a respective one of the light compensating areas 433, i.e., each of the gratings 44 is formed among four adjacent ones of the solar cells 43 proximate to one of the corners 432 of each of the four adjacent ones of the solar cells 43. The gratings 44 may be made of a material of silver, copper, or aluminum. In view of good reflectivity to light having a wavelength ranging from 330 nm to 1400 nm, silver or aluminum is preferable. Further, in consideration of cost factor, aluminum is more preferable.

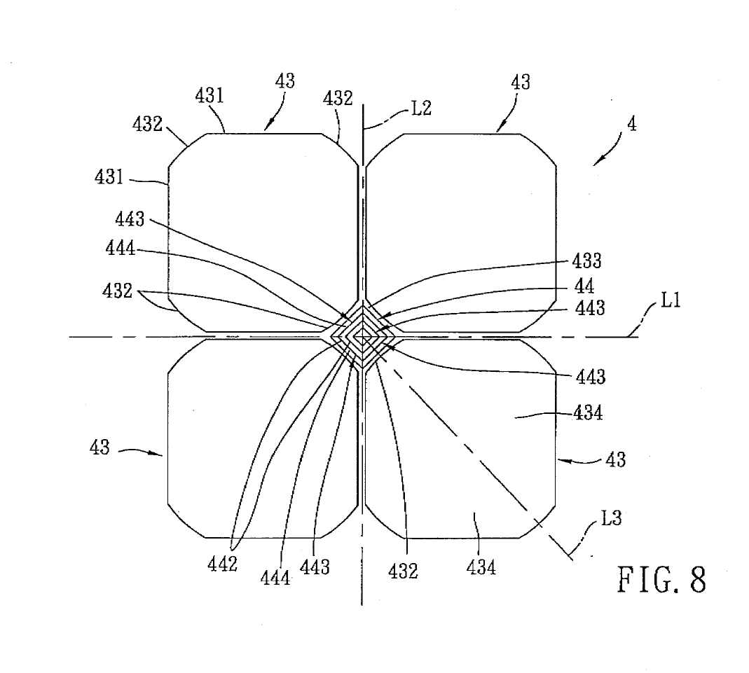

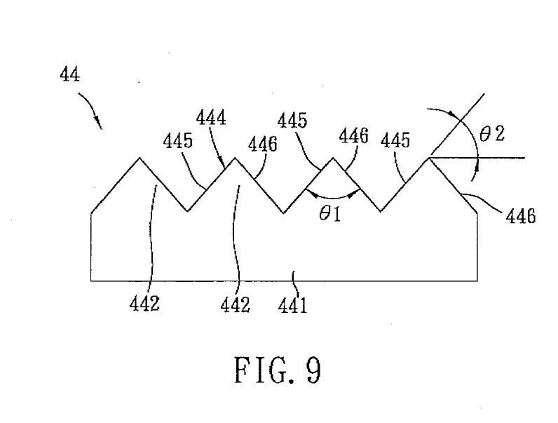

Referring to FIGS. 6, 8 and 9, each of the gratings 44 includes a body 441, and a plurality of microstructures 442 projecting from the body 441 towards the upper substrate 42. Each of the gratings 44 has a grating center which is an intersection of two lines L1, L2 shown in FIG. 8, and four reflecting regions 443 formed around the grating center. Each of the reflecting regions 443 has a light entrance face 444 that faces toward the upper substrate 42 and that is formed with the microstructures 442. Each of the microstructures 442 has a plurality of valleys and peaks. The valleys and peaks alternate with each other along a direction from the grating center to a corresponding one of the corners 432 of a corresponding one of the four adjacent ones of the solar cells 43 (the lines inside the gratings 44 of FIG. 8 are used to illustrate schematically the peaks of the microstructures 442). Each of the valleys and peaks in each of the reflecting regions 443 extends generally parallel to a respective one of the beveled sides of the corners 432 proximate to the corresponding one of the reflecting regions 443. Thus, the microstructures 442 are arranged and extend directionally.

The valleys and peaks on each light entrance face 444 form a plurality of V-shaped grooves each defined by first and second inclined faces 445, 446. An angle (θ1) between the first and second inclined faces 445, 446 is preferably 90°, but is not limited thereto. Thus, the diffraction of the light can be minimized, thereby preventing an adverse affect on the reflection of light. An angle (θ2) between the first inclined face 445 and a plane substantially parallel to a surface of the lower substrate 41 preferably ranges from 21° to 45°. When the angle (θ2) is in such a range, the incident light reflected to the upper substrate 42 by the microstructures 442 is likely to be totally reflected by the upper substrate 42. Therefore, most of the light can be reflected to the surrounding solar cells 43 (the light pathway is shown schematically by the arrows in FIG. 6), thereby enhancing the conversion efficiency.

In addition, the beveled side of the one of the corners 432 of each of the four adjacent ones of the solar cells 43 has a mid point. A line L3 passing through the mid point and the grating center divides the corresponding one of the solar cells 43 into two symmetrical areas 434. The line L3 also divides each of the reflecting regions 443 into two symmetrical areas.

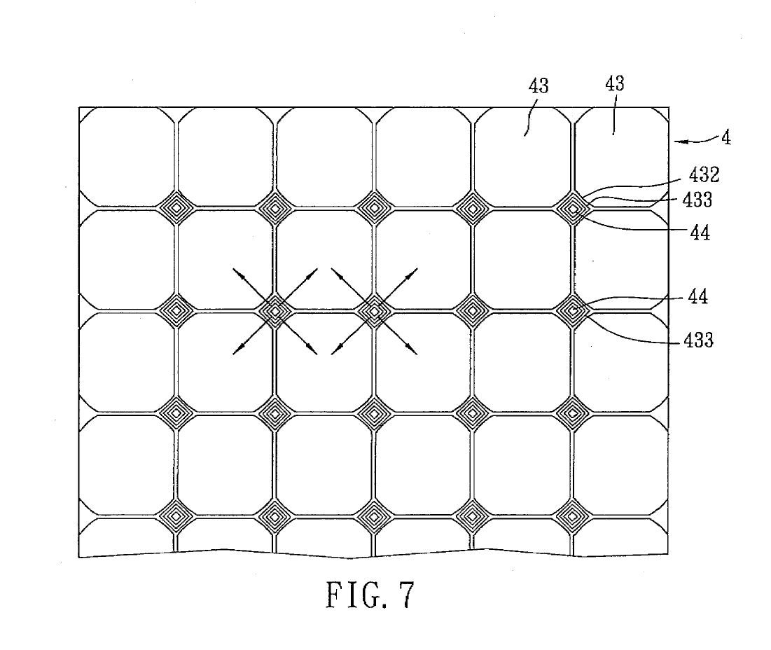

It is evident from the foregoing that each of the reflecting regions 443 corresponds to one of the four adjacent solar cells 43, and the positions of the reflecting regions 443 and the solar cells 43 are uniformly arranged. The function of the reflecting regions 443 is to reflect the incident light on the light compensating area 433 to the upper substrate 42, so as to be directed into the respective one of the solar cells 43 (the reflection directions of the light from the gratings 44 are shown schematically by the arrows in FIG. 7). By virtue of the positions of the reflecting regions 443 and the extension direction of the microstructures 442, an optimal reflection effect can be achieved. Therefore, the light incident on the light compensating areas 433 can be reflected to the solar cells 43, thereby increasing the light utilization rate and the photoelectric conversion efficiency.

The light-transmissive encapsulant 45 is disposed between the lower and upper substrates 41, 42 to encapsulate the solar cells 43 and the gratings 44. The light-transmissive encapsulant 45 has partitioning portions 451 between the gratings 44 and the solar cells 43 so as to electrically insulate the gratings 44 and the solar cells 43. The light-transmissive encapsulant 45 is made of, for example, ethylene-vinyl acetate copolymer (EVA), but is not limited thereto.

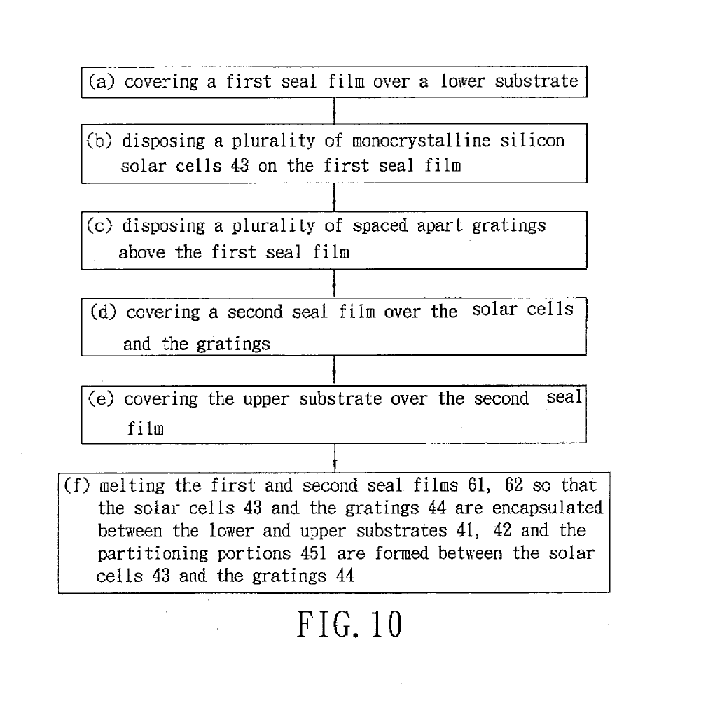

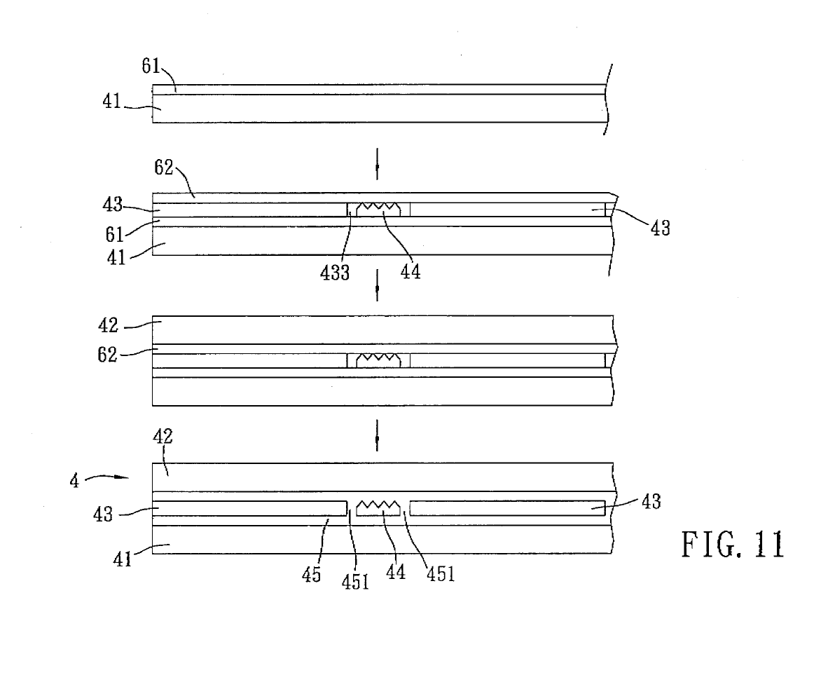

Referring to FIGS. 10 and 11, a method for forming the solar cell module 4 of the first preferred embodiment according to the present invention comprises:

(a) preparing the lower substrate 41 and covering a first seal film 61 on the lower substrate 41;

(b) disposing a plurality of monocrystalline silicon solar cells 43, each of which has at least four corners, on the first seal film 61 so that the solar cells 43 are spaced apart from each other and arranged in a matrix and each of the light compensating areas 433 is defined among the corners 432 of four adjacent ones of the solar cells 43;

(c) disposing each of the gratings 44 on the light compensating areas 433 so that the gratings 44 are separated from the solar cells 43;

(d) covering a second seal film 62 over the solar cells 43 and the gratings 44;

(e) covering the upper substrate 42 over the second seal film 62; and

(f) melting the first and second seal films 61, 62 so that the solar cells 43 and the gratings 44 are encapsulated between the lower and upper substrates 41, 42 and the partitioning portions 451 are formed between the solar cells 43 and the gratings 44 so as to separate the solar cells 43 from the gratings 44.

In an example of this invention, the first and second seal films 61, 62 are made of EVA.

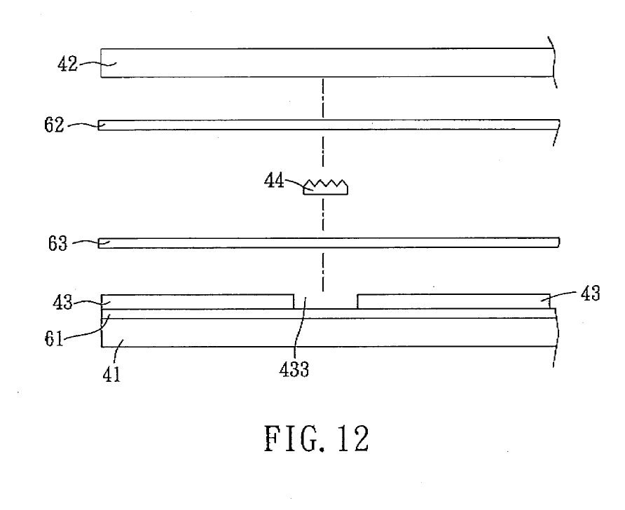

Referring to FIGS. 10 and 12, it is noted that the method further comprises a step of covering a third seal film 63 over the solar cells 43 before step (c), and, in step (c), the gratings 44 are disposed on the third seal film 63 at positions corresponding to the light compensating areas 433. In step (f), the first, second, and third seal films 61, 62 and 63 are melted together. With the third seal film 63, the electrical insulation between the solar cells 43 and the gratings 44 can be enhanced.

To sum up, compared to the above-mentioned US patents in the section of “Description of the Related Art”, the gratings 44 of the present invention are individual components and need not be formed integrally with the substrates. Therefore, a relatively thin substrate can be used, thereby reducing production costs. In addition, in accordance with the present invention, since the solar cells 43 are firstly arranged and then the gratings 44 are placed in the light compensating areas 433 among four adjacent ones of the solar cells 43, the manufacturing precision is easy to be controlled. Further, since each of the reflecting regions 443 and the microstructures 442 is designed to be arranged in a specific direction, the light incident on the reflecting regions 443 can be reflected effectively to the solar cells 43. For each of the solar cells 43, four regions proximate to the four corners 432 thereof can absorb the light reflected from the adjacent grating 44 so that the total area of the solar cells 43 can be irradiated uniformly, thereby generating uniform current to achieve an optimal utilization rate.

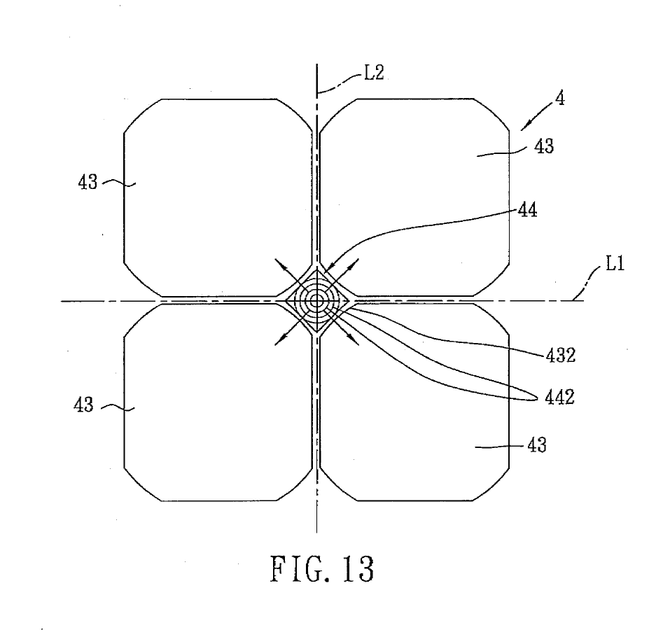

Referring to FIG. 13, the second preferred embodiment of a solar cell module 4 according to the present invention is shown. The difference between the solar cell module 4 of this embodiment and that of the first preferred embodiment is that, in this embodiment, each of the valleys and peaks of the microstructures 942 of the reflecting regions 443 extends in an arc shape substantially along the beveled side of the corners 432 proximate to the corresponding one of the reflecting regions 443. Therefore, the valleys and peaks in the four reflecting regions 443 form cooperatively concentric circles when reviewed from the top. Therefore, the light can be reflected to the respective solar cells 43 (the reflection directions of the light are shown schematically by the arrows in FIG. 13).

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A solar cell module, comprising:
lower and upper substrates that are spaced apart from each other, said upper substrate being light transmissive;
a plurality of spaced apart solar cells disposed between said lower and upper substrates and arranged in a matrix, each of said solar cells having at least four corners;
a plurality of gratings disposed between said lower and upper substrates, each of said gratings being formed among four adjacent ones of said solar cells proximate to one of said corners of each of said four adjacent ones of said solar cells, each of said gratings having a grating center and four reflecting regions formed around said grating center, each of said reflecting regions having a light entrance face that faces toward said upper substrate and that has a plurality of valleys and peaks, said valleys and peaks alternating with each other along a direction from said grating center to a corresponding one of said corners of a corresponding one of said four adjacent ones of said solar cells; and
a light-transmissive encapsulant disposed between said lower and upper substrates to encapsulate said solar cells and said gratings.

2. The solar cell module of claim 1, wherein each of said gratings is made of a material selected from the group consisting of silver, copper, and aluminum.

3. The solar cell module of claim 1, wherein said valleys and peaks on said light entrance face form a plurality of V-shaped grooves each defined by first and second inclined faces, an angle between said first inclined face and a plane substantially parallel to a surface of said lower substrate ranging from 21° to 45°.

4. The solar cell module of claim 1, wherein said light-transmissive encapsulant has partitioning portions between said gratings and said solar cells.

5. The solar cell module of claim 1, wherein said one of said corners of each of said four adjacent ones of said solar cells is beveled to form a beveled side that has a mid point, a line passing through said mid point and said grating center dividing the corresponding one of said solar cells into two symmetrical areas.

6. A method for forming a solar cell module, comprising:
(a) covering a first seal film over a lower substrate;
(b) disposing a plurality of solar cells, each of which has at least four corners, on the first seal film so that the solar cells are spaced apart from each other and arranged in a matrix;
(c) disposing a plurality of spaced apart gratings above the first seal film, each of the gratings being formed among four adjacent ones of the solar cells proximate to one of the corners of each of the four adjacent ones of the solar cells, each of the gratings having a grating center and four reflecting regions formed around the grating center, each of the reflecting regions having a light entrance face that faces away from the lower substrate and that has a plurality of valleys and peaks, the valleys and peaks alternating with each other along a direction from the grating center tea corresponding one of the corners of a corresponding one of the four adjacent ones of the solar cells;
(d) covering a second seal film over the solar cells and the gratings;
(e) covering an upper substrate over the second seal film; and
(f) melting the first and second seal films so that the solar cells and the gratings are encapsulated between the lower and upper substrates.

7. The method of claim 6, further comprising a step of covering a third seal film over the solar cells before step (c), wherein, in step (c), the gratings are disposed on the third seal film that is disposed above the lower substrate, and in step (f), the first, second, and third seal films are melted together.
